(19) United States
(12) Patent Application Publication
(10) Pub. No.: US 2010/0237346 A1
(43) Pub. Date: Sep. 23, 2010

(54) NONVOLATILE SEMICONDUCTOR MEMORY DEVICE AND METHOD OF MANUFACTURING THE SAME

(75) Inventors: Hiroshi Kanno, Kawasaki-shi (JP); Kenichi Murooka, Yokohama-shi (JP); Mitsuru Sato, Kamakura-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/556,102

(22) Filed: Sep. 9, 2009

(30) Foreign Application Priority Data
Mar. 17, 2009 (JP) 2009-065030

(51) Int. Cl. H01L 29/12; H01L 21/8246

(52) U.S. Cl. 257/49; 438/486; 257/E21.662; 257/E29.068; 257/E27.103

(57) ABSTRACT

A rectifier is formed by forming a first electrode layer, a semiconductor layer and a second electrode layer. A third electrode layer is formed between the first electrode layer and the semiconductor layer, or between the second electrode layer and the semiconductor layer.

The semiconductor layer and the third electrode layer are formed as follows. First, a first layer made from amorphous silicon and including a p-type first semiconductor region and an n-type second semiconductor region is deposited. Next, a second layer made from a metal is deposited on an upper or lower layer of the first layer. The third electrode layer including a metal silicide as a material lattice-matched to polysilicon is formed by siliciding the second layer. Next, the first layer is crystallized. Subsequently, the semiconductor layer is formed by activating an impurity included in the first layer and restoring crystal imperfections included in the first layer.

### CROSS-REFERENCE TO RELATED APPLICATION

This application is based on and claims the benefit of priority from prior Japanese Patent Application No. 2009-65030, filed on Mar. 17, 2009, the entire contents of which are incorporated herein by reference.

### BACKGROUND OF THE INVENTION

1. Field of the Invention

The present invention relates to a nonvolatile semiconductor memory device, more specifically to a nonvolatile semiconductor memory device configured as an arrangement of memory cells, each of the memory cells including a diode and a variable resistor connected in series, and a method of manufacturing the same.

2. Description of the Related Art

In recent years, along with a rising level of integration in semiconductor devices, circuit patterns of transistors and the like which configure the semiconductor devices are being increasingly miniaturized. Required in this miniaturization of the patterns is not simply a thinning of line width but also an improvement in dimensional accuracy and positional accuracy of the patterns. This trend applies also to semiconductor memory devices.

Conventionally known and marketed semiconductor memory devices such as DRAM, SRAM, and flash memory each use a MOSFET as a memory cell. Consequently, there is required, accompanying the miniaturization of patterns, an improvement in dimensional accuracy at a rate exceeding a rate of the miniaturization. As a result, a large burden is placed also on the lithography technology for forming these patterns which is a factor contributing to a rise in product cost.

In recent years, resistive memory is attracting attention as a candidate to succeed these kinds of semiconductor memory devices utilizing a MOSFET as a memory cell (refer, for example, to Japanese Unexamined Patent Application Publication (Translation of PCT Application) No. 2005-522045). The resistive memory devices herein include resistive RAM (ReRAM), in a narrow sense, that uses a transition metal oxide as a recording layer and stores its resistance states in a non-volatile manner, as well as Phase Change RAM (PCRAM) that uses chalcogenide or the like as a recording layer to utilize the resistance information of crystalline states (conductors) and amorphous states (insulators).

It is known that the variable resistance elements in resistive memory have two modes of operation. One is to set a high resistance state and a low resistance state by switching the polarity of the applied voltage, which is referred to as “bipolar type”. The other enables the setting of a high resistance state and a low resistance state by controlling the voltage values and the voltage application time, without switching the polarity of the applied voltage, which is referred to as “unipolar type”.

To achieve high-density memory cell arrays, the unipolar type is preferable. This is because that the unipolar type solution enables, without transistors, cell arrays to be configured by superposing variable resistance elements and rectifier elements, such as diodes, on respective intersections between bit lines and word lines. Moreover, large capacity may be achieved without an increase in cell array area by arranging such memory cell arrays laminated in a three-dimensional manner.

In a unipolar type ReRAM, data write to the memory cell is performed by applying a certain voltage to the variable resistance element for a short time. This allows the variable resistance memory cell to change from a high resistance state to a low resistance state. Such the operation for changing the variable resistance element from a high resistance state to a low resistance state is called “a setting operation”.

On the other hand, data erase of the memory cell is performed by applying a certain voltage that is smaller than that in the setting operation, to the variable resistance element having a low resistance state after the setting operation, for a longer time. This allows the variable resistance memory cell to change from a low resistance state to a high resistance state. Such the operation for changing the variable resistance element from a low resistance state to a high resistance state is called “a reset operation”. The memory cell is in a stable state in the high resistance state (the reset state), for example. If the memory cell stores 2-value data, data write thereto is performed by a setting operation that changes the reset state to a low resistance state.

During a reset operation, a large current of 1 μA or more serving as a resetting current must be passed through the memory cells. However in this case, there is a problem that a voltage occurring between memory cells after completion of the reset operation reaches a value extremely close to the setting voltage required in the previously mentioned setting operation, and an operating margin is small. The operating margin being small means it may occur that, after completion of the reset operation, the memory cells once more mistakenly undergo the setting operation, which is undesirable.

Moreover, in conventional resistive memory, there is a problem that a reverse leak current flowing in the transistor during write is not sufficiently reduced, and power consumption is large.

### SUMMARY OF THE INVENTION

In accordance with an aspect of the present invention, a method of manufacturing a nonvolatile semiconductor memory device comprising memory cells including a rectifier and a variable resistor connected in series is provided. The method includes forming a layer as the rectifier element. The method of forming a layer as the rectifier element further includes:

forming a first electrode layer, a semiconductor layer and a second electrode layer; and forming a third electrode layer between the first electrode layer and the semiconductor layer or between the second electrode layer and the semiconductor layer. The method of forming the semiconductor layer and the third electrode layer further includes: depositing a first layer formed of amorphous silicon and including a p type first semiconductor region and a n type second semiconductor region; depositing a second layer, the second layer formed of metal and on an upper layer or a lower layer of the first layer;
siliciding the second layer by heat treatment at a first temperature to form the third electrode layer formed of a metal silicide as a material lattice-matched with respect to polysilicon; crystallizing the first layer by heat treatment at a second temperature; and
activating an impurity included in the first layer and restoring crystal imperfection included in the first layer by heat treatment at a third temperature to form the semiconductor layer.

In accordance with another aspect of the present invention, a nonvolatile semiconductor memory device comprises a plurality of first lines and a plurality of second lines formed so as to intersect with each other, and memory cells each disposed at each of intersections of the first lines and the second lines and including a rectifier and a variable resistor connected in series.

The rectifier comprises: a semiconductor layer; a first electrode layer provided at one side of the semiconductor layer; a second electrode layer provided at the other side of the semiconductor layer; and a third electrode layer provided between the first electrode layer and the semiconductor layer or between the second electrode layer and the semiconductor layer. The semiconductor layer comprises a p type first semiconductor layer, and an n type second semiconductor layer. The third electrode layer is formed of a material lattice-matched with respect to the semiconductor layer, and the whole of the semiconductor layer has crystal growth generated from the third electrode layer as a crystal nucleus.

### BRIEF DESCRIPTION OF THE DRAWINGS

FIG. 1 is a block diagram of a nonvolatile semiconductor memory device in accordance with an embodiment of the present invention.

FIG. 2 is a circuit diagram of a memory cell array 1 and its peripheral circuits.

FIG. 3 is a perspective view of a part of the memory cell array 1.

FIG. 4 is a cross-sectional view of one memory cell taken along the line I-I′ and seen from the direction of the arrow in FIG. 3.

FIG. 5 is a view showing an example of a variable resistor VR.

FIG. 6 is a view showing an example of a variable resistor VR.

FIG. 7A is a cross-sectional view showing a manufacturing process for the nonvolatile semiconductor memory device in accordance with the embodiment of the present invention.

FIG. 7B is a cross-sectional view showing a manufacturing process for the nonvolatile semiconductor memory device in accordance with the embodiment of the present invention.

FIG. 7C is a cross-sectional view showing a manufacturing process for the nonvolatile semiconductor memory device in accordance with the embodiment of the present invention.

FIG. 7D is a cross-sectional view showing a manufacturing process for the nonvolatile semiconductor memory device in accordance with the embodiment of the present invention.

FIG. 7E is a cross-sectional view showing a manufacturing process for the nonvolatile semiconductor memory device in accordance with the embodiment of the present invention.

FIG. 7F is a cross-sectional view showing a manufacturing process for the nonvolatile semiconductor memory device in accordance with the embodiment of the present invention.

FIG. 7G is a cross-sectional view showing a manufacturing process for the nonvolatile semiconductor memory device in accordance with the embodiment of the present invention.

FIG. 8 is an enlarged cross-sectional view showing a manufacturing process for the nonvolatile semiconductor memory device in accordance with the embodiment of the present invention.

FIG. 9 is a view showing one example of current-voltage characteristics of the variable resistor VR and a diode DI.

FIG. 10 is an enlarged cross-sectional view showing a manufacturing process for a nonvolatile semiconductor memory device in accordance with a comparative example.

### DETAILED DESCRIPTION OF THE EMBODIMENTS

The embodiments of the invention will now be described in detail with reference to the drawings.

[Entire Configuration of a Nonvolatile Semiconductor Memory Device in Accordance with an Embodiment]

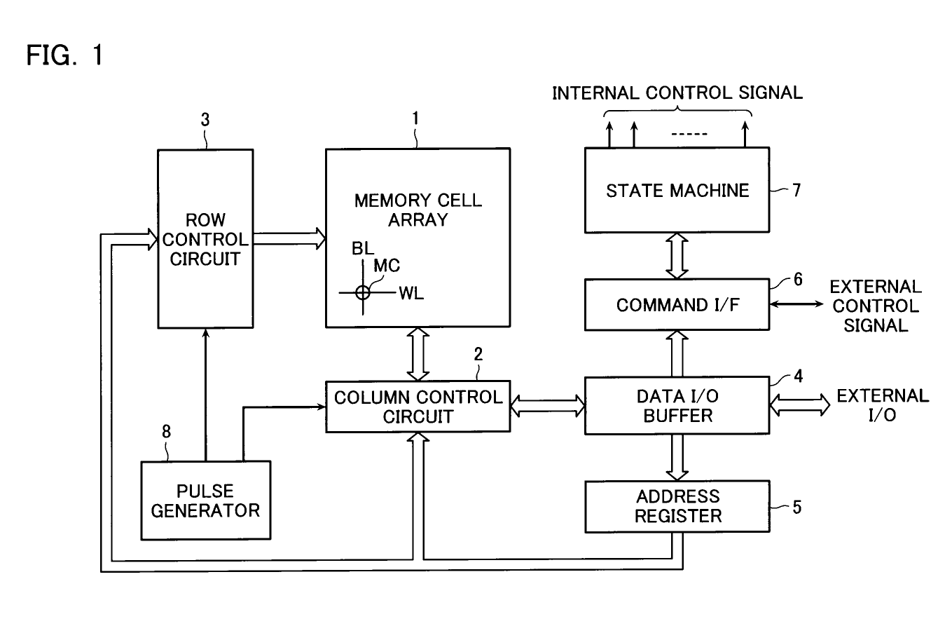

First, an entire configuration of a nonvolatile semiconductor memory device in accordance with an embodiment is described with reference to FIG. 1. FIG. 1 is a block diagram of a nonvolatile semiconductor memory device (nonvolatile memory) in accordance with the embodiment of the present invention.

The nonvolatile semiconductor memory device in accordance with the embodiment includes a memory cell array 1, a column control circuit 2, a row control circuit 3, a data I/O buffer 4, an address register 5, a command interface 6, a state machine 7, and a pulse generator 8.

The memory cell array 1 includes a plurality of word lines (first lines) WL and a plurality of bit lines (second lines) BL formed so as to intersect, and memory cells MC provided at intersections of the word lines WL and the bit lines BL. The memory cells MC are formed using ReRAM (a variable resistor) described hereafter.

The column control circuit 2 is provided at a position adjacent to the memory cell array 1 in the bit line BL direction. It controls the bit line BL in the memory cell array 1 to erase data from the memory cell, write data in the memory cell, and read data out of the memory cell.

The row control circuit 3 is provided at a position adjacent to the memory cell array 1 in the word line WL direction. It selects the word line WL in the memory cell array 1 and applies voltages required to erase data from the memory cell, write data in the memory cell, and read data out of the memory cell.

The data I/O buffer 4 is connected to an external host, not shown, via an I/O line to receive write data, receive erase instructions, provide read data, and receive address data and command data. The data I/O buffer 4 sends received write data to the column control circuit 2 and receives read-out data from the column control circuit 2 and provides it to external.

An address fed from external to the data I/O buffer 4 is sent via the address register 5 to the column control circuit 2 and the row control circuit 3.

A command fed from the host to the data I/O buffer 4 is sent to the command interface 6. The command interface 6 receives an external control signal from the host and decides whether the data fed to the data I/O buffer 4 is write data, a command or an address. If it is a command, then the command interface 6 transfers it as a received command signal to the state machine 7.

The state machine 7 manages the entire nonvolatile memory to receive commands from the host to execute read, write, erase, and execute data I/O management. The external host can also receive status information managed by the state machine 7 and decides the operation result. The status information is also utilized in control of write and erase.

The state machine 7 controls the pulse generator 8. Under this control, the pulse generator 8 is allowed to provide a pulse of any voltage at any timing. The pulse formed herein can be transferred to any line selected by the column control circuit 2 and the row control circuit 3. Peripheral circuit elements other than the memory cell array 1 can be formed in a Si substrate immediately beneath the memory cell array 1 formed in a wiring layer.

Thus, the chip area of the nonvolatile memory can be made almost equal to the area of the memory cell array 1.

[Circuit Configuration of the Nonvolatile Semiconductor Memory Device in Accordance with the Embodiment]

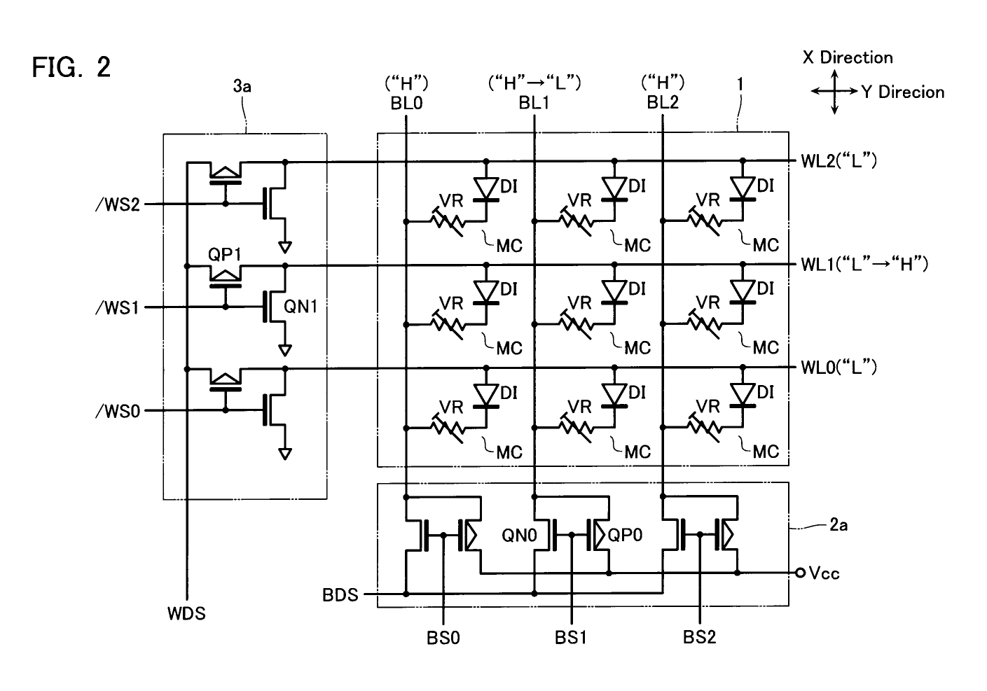

Next, a circuit configuration of a nonvolatile semiconductor memory device in accordance with the embodiment is described with reference to FIG. 2. FIG. 2 is a circuit diagram of the memory cell array 1 and its peripheral circuits.

As shown in FIG. 2, the nonvolatile semiconductor memory device includes the aforementioned memory cell array 1, a selection circuit 2a (part of the column control circuit 2), and a selection circuit 3a (part of the row control circuit 3).

The memory cell array includes the word lines WL (WL0˜WL2), the bit lines BL (BL0˜BL2), and the memory cells MC as mentioned above. The word lines WL0˜WL2 are formed so as to be arranged with a certain pitch in the X direction and to extend in the Y direction. The bit lines BL0˜BL2 are formed so as to be arranged with a certain pitch in the Y direction and to extend in the X direction. The memory cells MC are formed at intersections of the word lines WL0˜WL2 and the bit lines BL0˜BL2, that is to say, in a matrix formation.

Each of the word lines WL has one end connected to the selection circuit 3a, and each of the bit lines BL has one end connected to the selection circuit 2a. Each of the memory cells MC is configured by a diode (rectifier) DI and a variable resistor VR connected in series. The diode DI has an anode thereof connected to the word line WL, and a cathode thereof connected to the bit line BL via the variable resistor VR.

The selection circuit 2a includes a selection PMOS transistor QP0 and a selection NMOS transistor QN0, provided at each bit line BL, of which gates and drains are commonly connected. The selection PMOS transistor QP0 has a source connected to a high potential source Vcc. The selection NMOS transistor QN0 has a source connected to a bit line side drive sense line BDS, which is used to apply a write pulse and supply a detection current at the time of data read. The transistors QP0, QN0 have a common drain connected to the bit line BL, and a common gate supplied with a bit line selection signal BSi for selecting each bit line BL.

The selection circuit 3a includes a selection PMOS transistor QP1 and a selection NMOS transistor QN1, provided at each word line WL, of which gates and drains are commonly connected. The selection PMOS transistor QP1 has a source connected to a word line side drive sense line WDS, which is used to apply a write pulse and supply a detection current at the time of data read. The selection NMOS transistor QN1 has a source connected to a low potential source Vss. The transistors QP1, QN1 have a common drain connected to the word line WL and a common gate supplied with a word line selection signal /WSi for selecting each word line WL.

For example, in a case of executing various operations on the memory cell MC in the second row and second column shown in FIG. 2, the word line WL1 is set from “L” to “H”, and the other word lines WL0 and WL2 are maintained at “L”. In addition, the bit line BL1 is set from “H” to “L” and the other bit lines BL0 and BL2 are maintained at “H”. Here, a voltage applied to the memory cell MC is set to a voltage Vₛₑₜ during a write operation, is set to a voltage Vᵣₑₛₑₜ during an erase operation, and is set to a voltage V_{read} during a read operation. A magnitude relation of the voltages is V_{read} [symbol] Vᵣₑₛₑₜ [symbol] Vₛₑₜ

Note that the example shown above is suitable for selecting the memory cells individually. In contrast, in batch read of data from a plurality of memory cells MC connected to the selected word line WL1, sense amplifiers are arranged individually for each of the bit lines BL0˜BL2, and each of the bit lines BL0˜BL2 is connected to the individual sense amplifiers by the bit-line selection signal BS via the selection circuit 2a. Furthermore, the memory cell array 1 may have a polarity of the diode DI reversed from that of the circuit shown in FIG. 2 to supply a current flow from the bit line BL side to the word line WL side.

### [Lamination Structure of the Memory Cell Array 1]

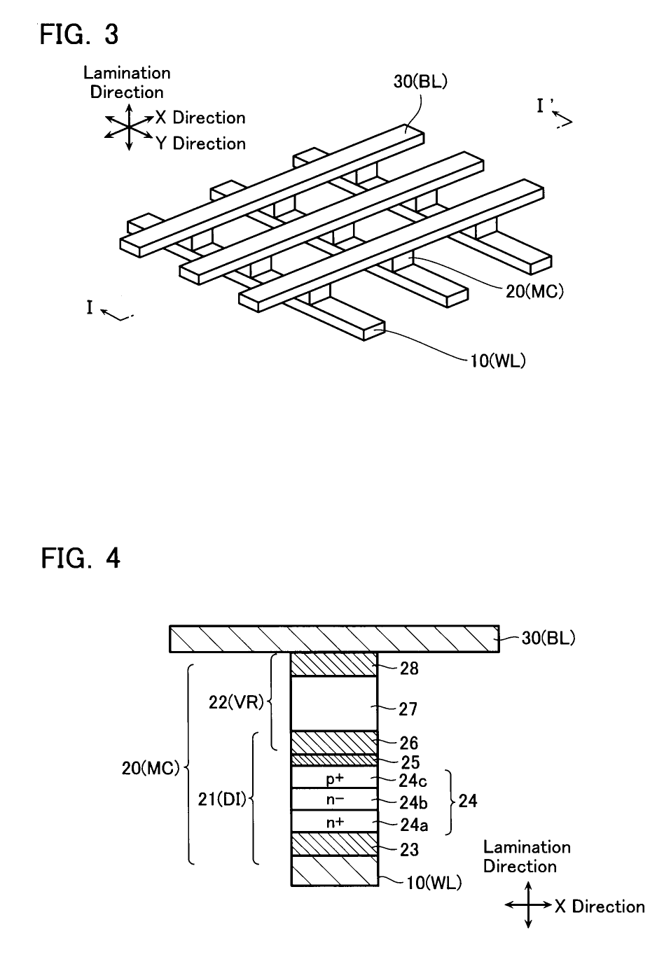

Next, a lamination structure of the memory cell array 1 is described with reference to FIG. 3. FIG. 3 is a schematic perspective view showing the lamination structure of the memory cell array 1.

The memory cell array 1 includes a first wiring layer 10 acting as the word lines WL (WL0˜WL2), a memory layer 20 acting as the memory cells MC, and a second wiring layer 30 acting as the bit lines BL (BL0˜BL2), as shown in FIG. 3.

The first wiring layer 10 is formed so as to extend in the Y direction with a certain pitch in the X direction, as shown in FIG. 3. The first wiring layer 10 is preferably made from a material with good heat resistance and a low resistance, for example, tungsten (W), tungsten silicide (WSi), nickel silicide (NiSi), cobalt silicide (CoSi), or the like.

The memory layer 20 is formed in column shapes on the first wiring layer 10, as shown in FIG. 3. The memory layer 20 is formed in a matrix formation in the X direction and the Y direction with a certain pitch.

The second wiring layer 30 is formed to be in contact with an upper surface of the memory layer 20 disposed in a line in the X direction, as shown in FIG. 3. The second wiring layer 30 is formed so as to extend in the X direction with a certain pitch in the Y direction. The second wiring layer 30 is preferably made from a material with good heat resistance and a low resistance, for example, tungsten (W), tungsten silicide (WSi), nickel silicide (NiSi), cobalt silicide (CoSi), or the like.

Next, a detailed lamination structure of the memory layer 20 is described. FIG. 4 is a cross-sectional view taken along the line I-I′ in FIG. 3.

The memory layer 20 includes a rectifier layer 21 acting as the diode (rectifier) DI and a variable resistance layer 22 acting as the variable resistor VR, as shown in FIG. 4.

The rectifier layer 21 includes an electrode layer 23, a semiconductor layer 24, an electrode layer 25, and an electrode layer 26, stacked sequentially on the first wiring layer 10, as shown in FIG. 4.

The electrode layer 23 and the electrode layer 26 function as a barrier metal and adhesive layer. The electrode layer 23 and the electrode layer 26 are made from titanium nitride (TiN).

The semiconductor layer 24 is made from polysilicon (poly-Si). As shown in FIG. 4, the semiconductor layer 24 includes, in order from a bottom layer to a top layer, an n+ type semiconductor layer 24a, an n− type semiconductor layer 24b, and a p+ type semiconductor layer 24c. The semiconductor layer 24 is uniformly crystallized, including almost no crystal grain boundaries. The whole of the semiconductor layer 24 has crystal growth generated from the electrode layer 25 as a crystal nucleus or crystal seed. Note that the “+” and “−” symbols indicate a level of an impurity concentration.

The electrode layer 25 is made from a material lattice-matched with respect to the semiconductor layer 24. The electrode layer 25 is made from titanium silicide (TiSi₂). Lattice mismatching of a (210) surface of the electrode layer 25 and a (111) layer of the semiconductor layer 24 (silicon (Si)) is 2.5% or less. That is to say, the electrode layer 25 is made from a material lattice-matched to the semiconductor layer 24.

The variable resistance layer 22 includes the above-mentioned electrode layer 26, as shown in FIG. 4. That is to say, the variable resistance layer 22 shares the electrode layer 26 with the rectifier layer 21. The variable resistance layer 22 further includes a resistance change layer 27 and an electrode layer 28 stacked sequentially on the electrode layer 26.

The resistance change layer 27 is made from a material in which a resistance can be varied by way of current, heat, chemical energy, and so on, according to an applied voltage. The electrode layer 28 functions as a barrier metal and adhesive layer. The electrode layer 28 is made from titanium nitride (TiN).

### [Configuration of the Resistance Change Layer 27]

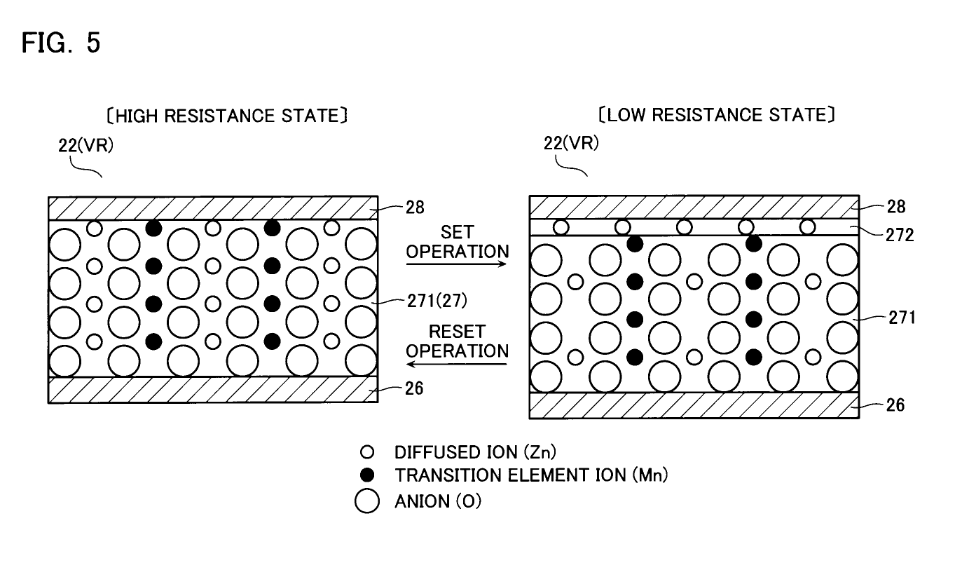

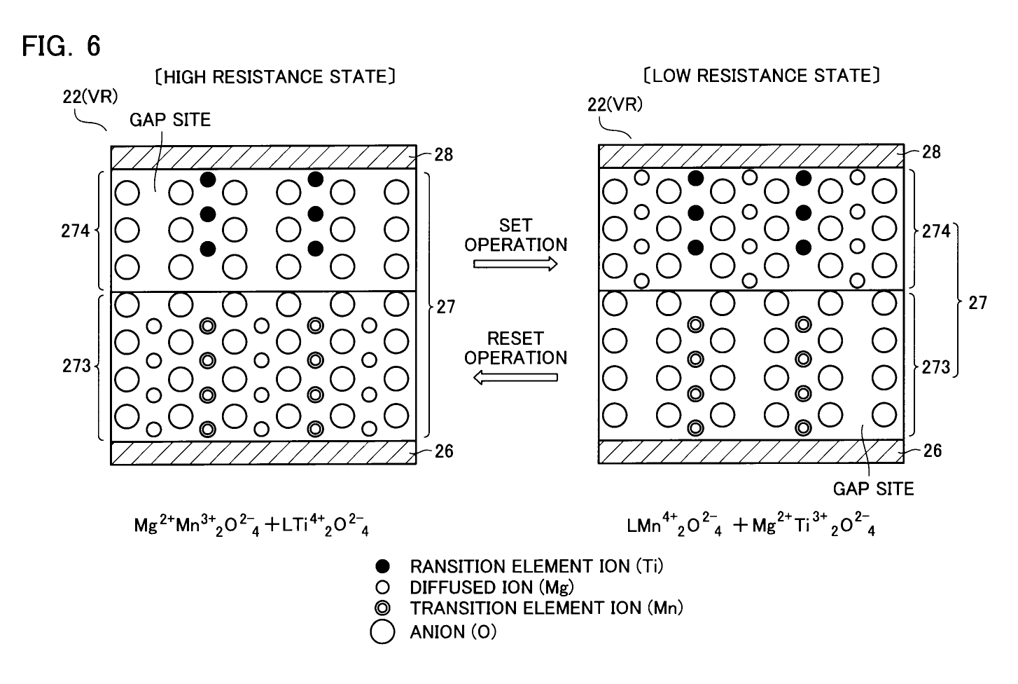

Next, a configuration of the resistance change layer 27 is described with reference to FIGS. 5 and 6.

FIGS. 5 and 6 are views showing the resistance change layer 27. The resistance change layer 27 may include one that comprises a composite compound containing cations of a transition element and varies the resistance through migration of cations (ReRAM).

The resistance change layer 27 shown in FIG. 5 is configured by a recording layer 271. The recording layer 271 is composed of a composite compound containing at least two types of cation elements. At least one of the cation elements is a transition element having the d-orbit incompletely filled with electrons, and the shortest distance between adjacent cation elements is 0.32 nm or lower. Specifically, it is represented by a chemical formula AₓM_{y}X_{z} (A and M are different elements) and may be formed of material having a crystal structure such as a spinel structure (AM₂O₄), an ilmenite structure (AMO₃), a delafossite structure (AMO₂), a LiMoN₂ structure (AMN₂), a wolframite structure (AMO₄), an olivine structure (A₂MO₄), a hollandite structure (AₓMO₂), a ramsdellite structure (AₓMO₂), and a perovskite structure (AMO₃).

In the example of FIG. 5, ZnMn₂O₄ is used, A comprising Zn, M comprising Mn, and X comprising O. The recording layer 271 may also be configured by a thin film made from one of materials such as NiO, TiO₂, SrZrO₃, and Pr_{0.7}Ca_{0.3}MnO₃.

In the recording layer 271 of FIG. 5, a small white circle represents a diffused ion (Zn), a large white circle represents an anion (O), and a small black circle represents a transition element ion (Mn). An initial state of the recording layer 271 is a high-resistance state. When the electrode layer 26 is kept at a fixed potential and a negative voltage is applied to the electrode layer 28, part of diffused ions in the recording layer 271 migrate toward the electrode layer 28 to reduce diffused ions in the recording layer 271 relative to anions. The diffused ions arrived at the electrode layer 28 accept electrons from the electrode layer 28 and precipitate as a metal, thereby forming a metal layer 272. Inside the recording layer 271, anions become excessive and consequently increase the valence of the transition element ion in the recording layer 271. As a result, the carrier injection brings the recording layer 271 into electron conduction and thus completes setting. On data reading, a current may be allowed to flow, of which value is very small so that the material configuring the recording layer 271 (resistance change layer 27) causes no resistance variation. A programmed state (low-resistance state) may be reset to the initial state (high-resistance state) by supplying a large current flow in the recording layer 271 for a sufficient time, which causes Joule heating to facilitate the oxidation reduction reaction in the recording layer 271. Application of an electric field in the opposite direction from that at the time of setting may also allow resetting.

The resistance change layer 27 shown in FIG. 6 is configured by two layers: a first compound layer 273 and a second compound layer 274. The first compound layer 273 is arranged on a side close to the electrode layer 26 and represented by a chemical formula AₓM1_{y}X1_{z}. The second compound layer 274 is arranged on a side close to the electrode layer 28 and has gap sites capable of accommodating cation elements from the first compound layer 273.

In the example of FIG. 6, A comprises Mg, M1 comprises Mn, and X1 comprises O in the first compound layer 273. The second compound layer 274 contains Ti shown with black circles as transition element ions. In the first compound layer 273, a small white circle represents a diffused ion (Mg), a large white circle represents an anion (O), and a double circle represents a transition element ion (Mn). The first compound layer 273 and the second compound layer 274 may be stacked in multiple layers such as two or more layers.

In the example shown in FIG. 6, potentials are given to the electrode layers 26, 28 so that the first compound layer 273 serves as an anode and the second compound layer 274 serves as a cathode to cause a potential gradient in the resistance change layer 27. In this case, part of diffused ions in the first compound layer 273 migrate through the crystal and enter the second compound layer 274 on the cathode side. The crystal of the second compound layer 274 includes gap sites capable of accommodating diffused ions. Accordingly, the diffused ions moved from the first compound layer 273 are trapped in the gap sites. Therefore, the valence of the transition element ion in the first compound layer 273 increases while the valence of the transition element ion in the second compound layer 274 decreases. In the initial state, the first and second compound layers 273, 274 may be in the high-resistance state. In such a case, migration of part of diffused ions in the first compound layer 273 therefrom into the second compound layer 274 generates conduction carriers in the crystals of the first and second compounds, and thus both have electric conduction. The programmed state (low-resistance state) may be reset to an erased state (high-resistance state) by supplying a large current flow in the resistance change layer 27 for a sufficient time for Joule heating to facilitate the oxidation reduction reaction in the resistance change layer 27, as in the preceding example. Application of an electric field in the opposite direction from that at the time of setting may also allow reset.

[Method of Manufacturing the Nonvolatile Semiconductor Memory Device in Accordance with the Embodiment]

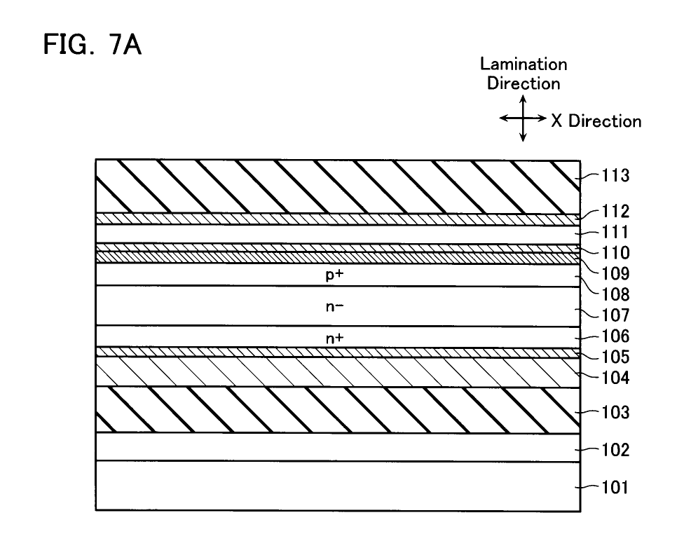

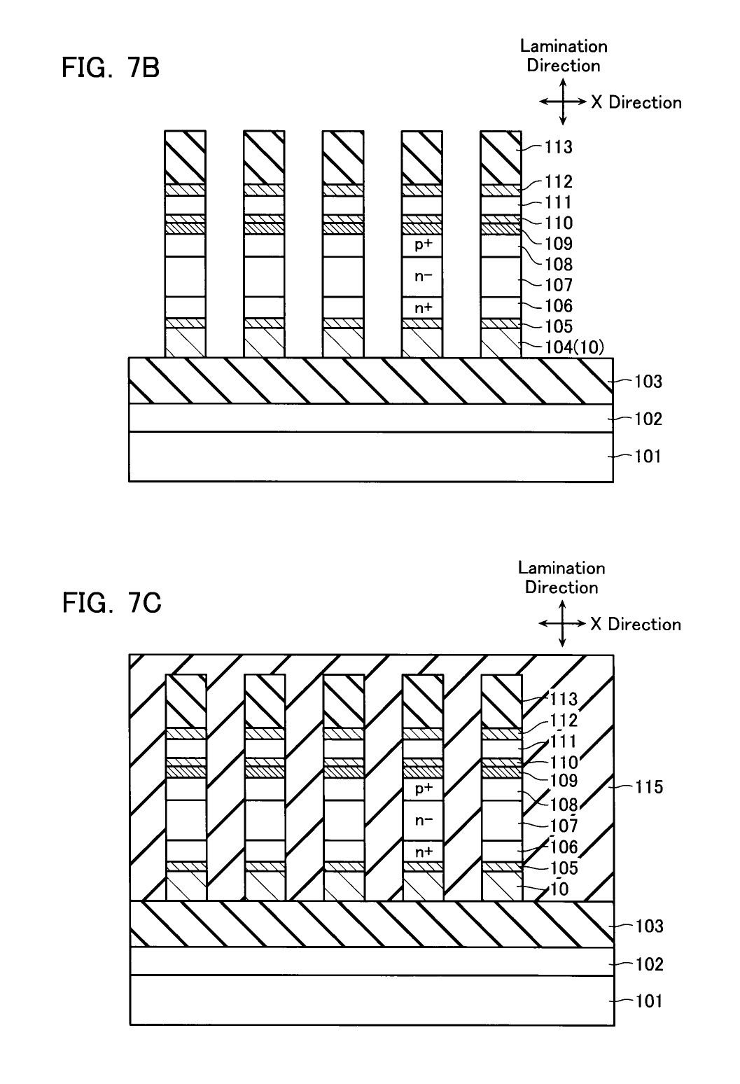

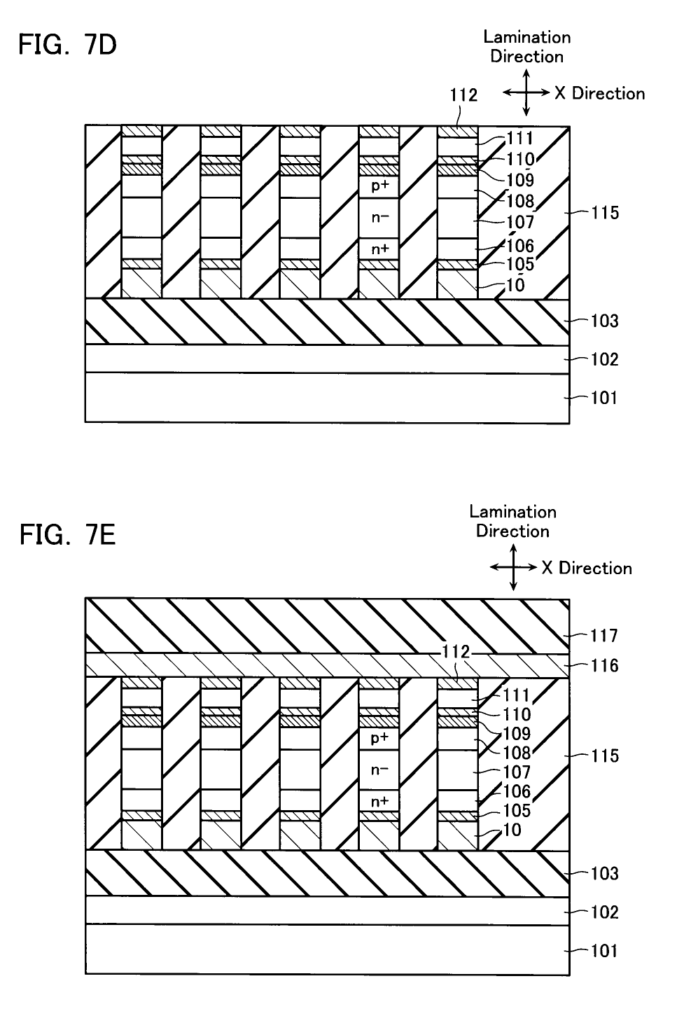

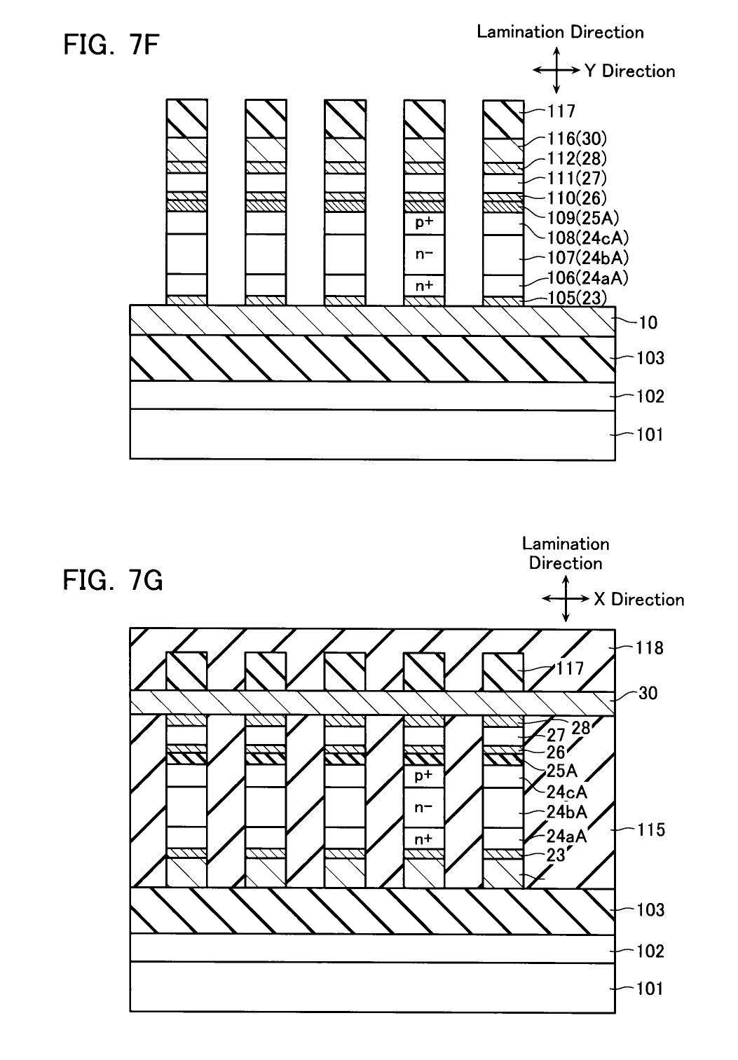

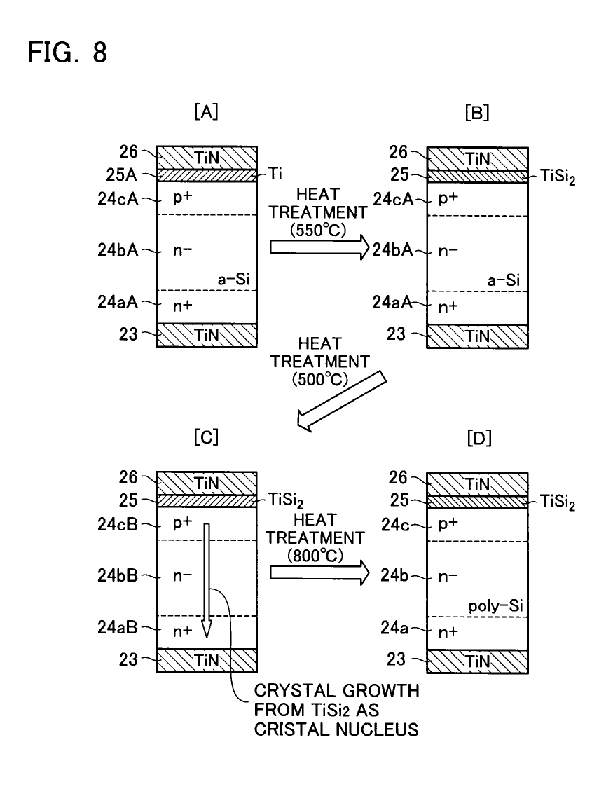

Next, a method of manufacturing the nonvolatile semiconductor memory device in accordance with the embodiment is described with reference to FIGS. 7A-7G and FIG. 8. FIGS. 7A-7G are cross-sectional views showing a manufacturing process for the nonvolatile semiconductor memory device in accordance with the embodiment. FIG. 8 is an enlarged cross-sectional view showing a manufacturing process.

First, as shown in FIG. 7A, on one surface of a silicon substrate 101 having a thickness of 720 μm there is formed a CMOS circuit layer 102 that includes various kinds of CMOS circuit, and so on. Formed sequentially on the CMOS circuit layer 102 are an insulating film 103, a composite film 104, a titanium nitride film 105, an n+ type semiconductor region 106, an n− type semiconductor region 107, a p+ type semiconductor region 108, a titanium film 109, a titanium nitride film 110, a resistance change material film 111, a titanium nitride film 112, and an insulating film 113.

The CMOS circuit layer 102 is formed using a normal CMOS process. The CMOS circuit layer 102 includes a MOSFET included in such as a peripheral circuit, not shown, and multi-layered wiring for supplying various kinds of voltages and signals to the peripheral circuit and so on; in addition, the CMOS circuit layer 102 includes wiring portions and so on for connection to the memory cell array 1.

The insulating film 103 is formed by performing CVD with TEOS as a main material to deposit a silicon oxide film (SiO₂) with a film thickness of about 300 nm on the CMOS circuit layer 102.

The composite film 104 is configured as a stacked structure of a layer of titanium nitride (TiN) with a film thickness of 10 nm, and a layer of tungsten (W) with a film thickness of 50 nm formed on the insulating film 103, and is formed by sputtering. The composite film 104 later becomes the aforementioned first wiring layer 10.

The titanium nitride film 105 is formed by, using a sputtering method, depositing a film of titanium nitride (TiN) with a film thickness of 10 nm on the composite film 104. The titanium nitride film 105 functions as a metal barrier for suppressing unnecessary diffusion of impurity into the n+ type semiconductor region 106. The titanium nitride film 105 later becomes the aforementioned electrode layer 23.

The n+ type semiconductor region 106 is formed by depositing a film of amorphous silicon with a film thickness of 10 nm on the titanium nitride film 105, and then injecting the thus-created film with ions of arsenic (As) at an accelerating voltage of 1 keV. The n+ type semiconductor region 106 is an n+ type silicon layer formed by injecting arsenic (As) to an impurity concentration of about 10²⁰ cm⁻³, and later becomes the aforementioned n+ type semiconductor layer 24a.

The n− type semiconductor region 107 is formed on the above-described n+ type semiconductor region 106. The n− type semiconductor region 107 is formed as follows. First, a film of amorphous silicon with a film thickness of 90 nm is deposited. Thereafter, the film is then injected with ions of arsenic (As) at an accelerating voltage of 75 keV. As a result, an intrinsic i-type semiconductor region 107 with a film thickness of 90 nm and including on average 10¹⁷ cm⁻³ of arsenic (As) is formed. The intrinsic i-type semiconductor region 107 later becomes the aforementioned n− type semiconductor layer 24b.

The p+ type semiconductor region 108 is formed on the above-described n− type semiconductor region 107. The p+ type semiconductor region 108 is formed by injecting ions of boron (B) at an accelerating voltage of 1 keV into the n− type semiconductor region 107 to change an upper portion of the n− type semiconductor region 107 into a p+ type semiconductor region. The p+ type semiconductor region 108 can, for example, be set to a region with a film thickness of 10 nm and including about 10²⁰ cm⁻³ of boron (B). The p+ type semiconductor region 108 later becomes the aforementioned p+ type semiconductor layer 24c.

The titanium film 109, the titanium nitride film 110, the resistance change material film 111, and the titanium nitride film 112 are formed sequentially on the above-described p+ type semiconductor region 108 by sputtering. The titanium film 109 is formed with a film thickness of 3 nm and later becomes the electrode layer 25. The titanium nitride film 110 is formed with a film thickness of 10 nm and later becomes the electrode layer 26. The resistance change material film 111 is formed from ZnMn₂O₄ with a film thickness of 10 nm and later becomes the resistance change layer 27. The titanium nitride film 112 is formed with a film thickness of 10 nm and later becomes the electrode layer 28.

The insulating film 113 is formed, by using CVD with TEOS as a main material, by depositing silicon oxide (film thickness: 150 nm) on the above-described resistance change material film 111.

Next, as shown in FIG. 7B, the composite film 104, the titanium nitride film 105, the n+ type semiconductor region 106, the n− type semiconductor region 107, the p+ type semiconductor region 108, the titanium film 109, the titanium nitride film 110, the resistance change material film 111, the titanium nitride film 112, and the insulating film 113 are patterned in stripes having a certain pitch in the X direction. First, an imprint lithography technology is used to form a resist pattern having a pitch of 44 nm in the X direction, the thus-obtained resist pattern being used as a mask in a reactive ion etching utilizing CHF₃ and CO gas, thereby patterning the insulating film 113. Here, after stripping the resist, a pattern formed due to the insulating film 113 is used as an etching mask in a reactive ion etching utilizing Cl₂, Ar, and CO gas, thereby sequentially patterning the titanium nitride film 112 through the titanium nitride film 105.

Then, as shown in FIG. 7B, a reactive ion etching utilizing CHF₃ and SF₆ is used to pattern the composite film 104 in stripes having a certain pitch in the X direction. Through the patterning, the composite film 104 becomes the first wiring layer 10.

Subsequently, as shown in FIG. 7C, CVD with TEOS as a main material is used to form an insulating film 115 constituted by silicon oxide (SiO₂). Next, as shown in FIG. 7D, CMP is used to planarize the insulating film 113 and the insulating film 115 with the titanium nitride film 112 as a stopper. Then, as shown in FIG. 7E, sputtering is used to form a composite film 116 constituted by stacking titanium nitride (TiN) with a film thickness of 10 nm and tungsten (W) with a film thickness of 50 nm. Then, CVD with TEOS as a main material is used to form an insulating film 117 constituted by silicon oxide (SiO₂).

Next, as shown in FIG. 7F, each layer is processed in stripes having a certain pitch in the Y direction. That is to say, an imprint lithography technology is used to form a striped resist pattern having a pitch of 44 nm in the Y direction, the thus-obtained resist pattern being used as a mask in a reactive ion etching utilizing CHF₃ and CO gas, thereby patterning the silicon oxide film 117.

Then, after stripping the resist, the patterned insulating film 117 is used as an etching mask in a reactive ion etching utilizing CHF₃ and SF₆ gas, thereby patterning the composite film 116. Through the patterning, the composite film 116 becomes the second wiring layer 30.

Subsequently, a reactive ion etching utilizing Cl₂, Ar, and CO gas is used to sequentially pattern the titanium nitride film 112, the resistance change material film 111, the titanium nitride film 110, the titanium film 109, the p+ type semiconductor region 108, the n− type semiconductor region 107, the n+ type semiconductor region 106, and the titanium nitride film 105. Note that in this process, the n+ type semiconductor region 106 and the titanium nitride film 105 need not be completely divided from each other by etching. Through the patterning, the titanium nitride film 105 becomes the electrode layer 23; the n+ type semiconductor region 106 becomes a columnar n+ type semiconductor layer 24aA; the n− type semiconductor region 107 becomes a columnar n− type semiconductor layer 24bA; the p+ type semiconductor region 108 becomes a columnar p+ type semiconductor layer 24cA; the titanium film 109 becomes an electrode layer 25A; the titanium nitride film 110 becomes the electrode layer 26; the resistance change material film 111 becomes the resistance change layer 27; and the titanium nitride film 112 becomes the electrode layer 28.

Next, as shown in FIG. 7G, a silicon oxide film capable of spin coating is used to fill trenches due to the above-described patterning and, while doing so, form an insulating film 118 constituted by silicon oxide on the entire surface of a wafer.

Next, heat treatment processes following FIG. 7G are described with reference to FIG. 8. As described above, a process shown in FIG. 7G is executed to form the electrode layer 23, the n+ type semiconductor layer 24aA, the n− type semiconductor layer 24bA, the p+ type semiconductor layer 24cA, the electrode layer 25A, and the electrode layer 26, as shown in [A] of FIG. 8.

Next, as shown in [B] of FIG. 8, a heat treatment at about 550° C.±20° C. (3 minutes) is implemented (first heat treatment process). As a result, the electrode layer 25A made from titanium (Ti) reacts with (is silicided by) the p+ type semiconductor layer 24cA made from silicon (Si) to become the electrode layer 25 made from titanium silicide (TiSi₂).

Subsequently, as shown in [C] of FIG. 8, a heat treatment at about 500° C.±20° C. (2 hours) is implemented (second heat treatment process). As a result, the n+ type semiconductor layer 24aA, the n− type semiconductor layer 24bA, and the p+ type semiconductor layer 24cA, each made from amorphous silicon, undergo crystal growth from the electrode layer 25 (titanium silicide (TiSi₂)) as a crystal nucleus to become an n+ type semiconductor layer 24aB, an n− type semiconductor layer 24bB, and a p+ type semiconductor layer 24cB, each made from polysilicon, respectively. That is to say, the layers are crystallized by the heat treatment at about 500° C.±20° C. (2 hours) from the electrode layer 25 as a starting point, and at least beyond a border between the p+ type semiconductor layer 24cA and the n− type semiconductor layer 24bA. Preferably, the layers are crystallized over an entirety of the p+ type semiconductor layer 24cA, the n− type semiconductor layer 24bA, and the n+ type semiconductor layer 24aA, from the electrode layer 25 as a starting point.

Next, as shown in [D] of FIG. 8, a heat treatment at about 800° C.±50° C. (5 seconds) is implemented (third heat treatment process). As a result, the n+ type semiconductor layer 24aB, the n− type semiconductor layer 24bB, and the p+ type semiconductor layer 24cB have an impurity therein electrically activated and at the same time have crystal imperfections formed in polysilicon crystals therein restored. The n+ type semiconductor layer 24aB, the n− type semiconductor layer 24bB, and the p+ type semiconductor layer 24cB become the n+ type semiconductor layer 24a, the n− type semiconductor layer 24b, and the p+ type semiconductor layer 24c, each of which have the impurity electrically activated and include few crystal imperfections, respectively.

[Advantage of the Nonvolatile Semiconductor Memory Device in Accordance with the Embodiment]

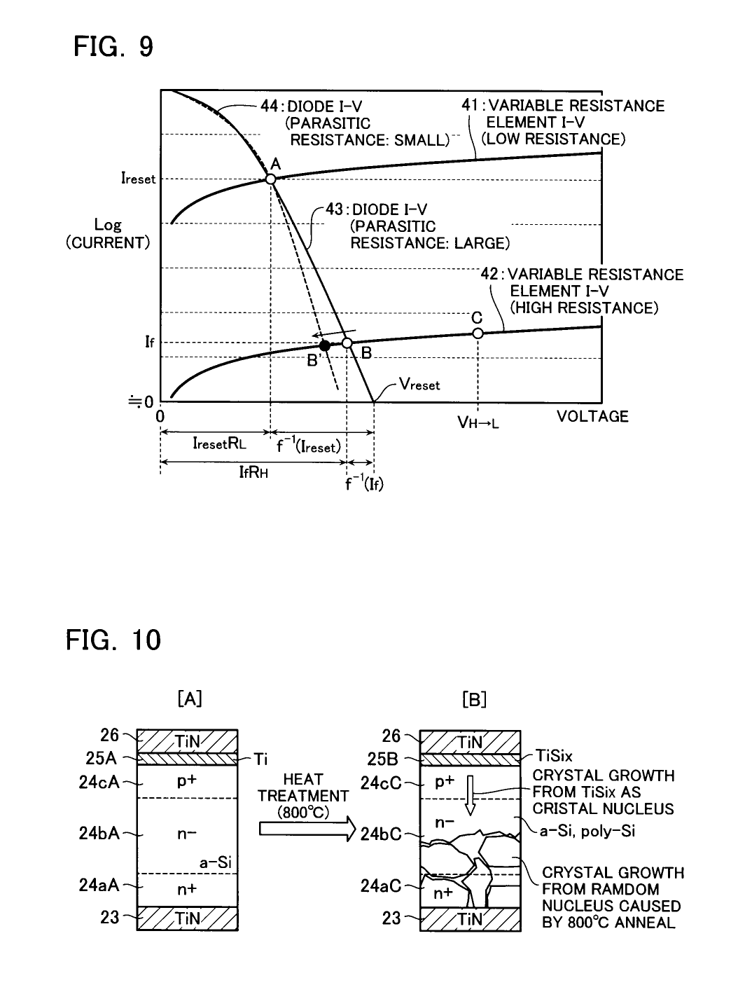

Next, an advantage of the nonvolatile semiconductor memory device in accordance with the embodiment is described. First, problems relating to current-voltage characteristics of the variable resistor VR and the diode DI are described with reference to FIG. 9. FIG. 9 is a view showing one example of the current-voltage characteristics of the variable resistor VR and the diode DI. In FIG. 9, a horizontal axis shows a voltage and a vertical axis shows a current. Since the vertical axis is a logarithmic display, a point where the current=0 cannot be defined; however, for convenience of explanation herein, a bottom extremity of the vertical axis is taken as the point where the current=0.

FIG. 9 shows current-voltage characteristics 41˜44. The current-voltage characteristic 41 is a current-voltage characteristic of the variable resistor VR in the low-resistance state. The current-voltage characteristic 42 is a current-voltage characteristic of the variable resistor VR in the high-resistance state. The current-voltage characteristic 43 is a current-voltage characteristic of the diode DI when a diode factor is large. The current-voltage characteristic 44 is a current-voltage characteristic of the diode DI when the diode factor is small. Note that the diode factor is an index showing a steepness of rise in a forward direction current flowing in the diode DI; the smaller the diode factor, the steeper the current-voltage characteristic of the diode DI.

In addition, FIG. 9 shows a current Iᵣₑₛₑₜ. The current Iᵣₑₛₑₜ is a current flowing in the memory cell MC when the variable resistor VR is reset from the low-resistance state to the high-resistance state. Note that, in FIG. 9, the current-voltage characteristics 43 and 44 of the diode DI have a direction of the voltage (horizontal axis) inverted and are plotted to intersect with a point A where the current Iᵣₑₛₑₜ flows. This is to facilitate distinguishing between a voltage applied to the variable resistor VR and a voltage applied to the diode DI.

Additionally in FIG. 9, a resistance of the variable resistor VR in the low-resistance state is set to R_{L} and a resistance of the variable resistor VR in the high-resistance state is set to R_{H}. Here, the current-voltage characteristic of the diode DI is defined by a function f, and its inverse function is defined by an inverse function f⁻¹. Thus, the relation between the current and the voltage is expressed as I=f(V), and V=f⁻¹(I). Now, if a voltage applied to the memory cell MC during a reset operation is defined as Vᵣₑₛₑₜ, then a relation in (expression 1) shown below is established for a state immediately prior to resetting (point A).

IᵣₑₛₑₜR_{L}+f⁻¹(Iᵣₑₛₑₜ)=Vᵣₑₛₑₜ (Expression 1)

A first entry on a left-hand side of the above-described (expression 1) shows a voltage applied to the variable resistor VR when the current Iᵣₑₛₑₜ flows in the memory cell MC, and a second entry on the left-hand side of the above-described (expression 1) shows a voltage applied to the diode DI.

Meanwhile, when a parasitic resistance of the diode DI is large, a current flowing in the memory cell MC immediately after resetting moves along the current-voltage characteristic 43 of the diode DI from the point A to a point B. If a current flowing in the memory cell MC at this time is defined as I_{f}, then, since a voltage applied to the memory cell MC does not change, a relation in (expression 2) shown below is established.

I_{f}R_{H}+f⁻¹(I_{f})=Vᵣₑₛₑₜ (expression 2)

Consequently, a voltage I_{f}R_{H} applied to the variable resistor VR immediately after resetting can be expressed by (expression 3) shown below.

I_{f}R_{H}=IᵣₑₛₑₜR_{L}+f⁻¹(Iᵣₑₛₑₜ)−f⁻¹(I_{f}) (expression 3)

Here, it is assumed that the voltage I_{f}R_{H} is larger than a voltage V_{H♯L} (point C). The voltage V_{H→L} (point C) is a voltage when the variable resistor VR switches from the high-resistance state to the low-resistance state. In this case, the variable resistor VR returns again (is set anew) to the low-resistance state in spite of the fact that a reset operation has been executed, and a desired operation on the memory cell MC is not executed.

As is clear from the above-described (expression 1) through (expression 3), to avoid the above-described re-setting and obtain a sufficient operation margin, “f⁻¹(Iᵣₑₛₑₜ)−f⁻¹(I_{f})” need only be made smaller, that is to say, a gradient of “f⁻¹” need only be made more gentle. As mentioned above, “f⁻¹” is the inverse function of the current-voltage characteristic f of the diode DI. Accordingly, it can be rephrased that a requirement for obtaining a sufficient operation margin is to steepen the current-voltage characteristic of the diode DI until “Iᵣₑₛₑₜ” is reached. In other words, if the current-voltage characteristic of the diode DI in FIG. 9 is changed from a state “43” to a state “44”, the operation point immediately after resetting is shifted from the point B to a point B′, thereby the operation margin can be secured.

Next, a means for steepening the current-voltage characteristic of the diode DI is considered. When the diode DI is applied with a voltage lower than an built-in potential in a pn junction of the diode DI, a current flows in the diode DI mainly due to conduction of carriers through a trap level in a forbidden band of the pn junction. On the other hand, when a voltage equal to or greater than the built-in potential is applied thereto, the current flows mainly due to carrier diffusion in the pn junction. Consequently, in order to steepen the current-voltage characteristic in a region where a voltage is small, it is necessary to suppress the former, i.e., a current through the trap level. The trap level density increases with an increase in a density of crystal grain boundaries or crystal imperfections of silicon. Accordingly, in order to achieve the above-mentioned purpose, it is necessary to reduce a crystal imperfection density of the silicon.

Meanwhile, in a setting operation for switching the variable resistor VR of a selected memory cell MC from the high-resistance state to the low-resistance state, a voltage of about 2.5V˜4V must be applied to the selected memory cell MC. At this time, the diode DI in a non-selected memory cell MC is in a reverse biased state. Consequently, when the reverse direction leak current of the diode DI is large, the setting operation in the non-selected memory cell MC will be executed (false setting). Furthermore, even if a probability of false setting can be sufficiently suppressed, a large number of memory cells MC in total causes a total of the reverse direction leak current to become large.

Therefore, in order to lower power consumption, it is desirable to reduce the reverse direction leak current as much as possible. Here, the reverse direction leak current flows mainly through the trap level in a depletion layer of a pn junction diode. Accordingly, there is a need to reduce the crystal imperfection density of the silicon in view of preventing false setting due to the reverse direction leak current, and in view of lowering power consumption.

To deal with the above-described problem, the nonvolatile semiconductor memory device in accordance with the embodiment has the electrode layer 25 (titanium silicide) provided between the semiconductor layer 24 (polysilicon) and the electrode layer 26 (titanium nitride). The electrode layer 25 is configured by a material lattice-matched with respect to the semiconductor layer 24. As a result of this configuration, the semiconductor layer 24 is uniformly crystallized, including almost no crystal grain boundaries. That is to say, the nonvolatile semiconductor memory device in accordance with the embodiment can provide a nonvolatile semiconductor memory device having high reliability, in which the crystal imperfection density of the semiconductor layer 24 (polysilicon) is reduced, whereby effectively suppressing occurrence of a false setting operation at a time of a reset operation while at the same time lowering power consumption.

Next, an effect of the method of manufacturing a nonvolatile semiconductor memory device in accordance with the embodiment is described with reference to FIG. 10. FIG. 10 is an enlarged cross-sectional view showing a manufacturing process for a nonvolatile semiconductor memory device in accordance with a comparative example. In the comparative example shown in FIG. 10, steps of FIG. 7A to FIG. 7G are executed in a similar way to those of the present embodiment. In the comparative example, a heat treatment at 800° C. is executed subsequent to FIG. 7G, as shown in FIG. 10. As a result, the electrode layer 25A becomes a layer configured by TiSix. Moreover, in the n+ type semiconductor layer 24aA, the n− type semiconductor layer 24bA, and the p+ type semiconductor layer 24cA, each made from amorphous silicon, a crystal nucleus occurs randomly or spontaneously at a random position and crystal growth proceeds centering on the crystal nucleus. As a result, the n+ type semiconductor layer 24aA, the n− type semiconductor layer 24bA, and the p+ type semiconductor layer 24cA become, respectively, polycrystalline bodies 24aC˜24cC that include a large number of crystal grain boundaries and crystal imperfections.

In contrast, in the method of manufacturing a nonvolatile semiconductor memory device in accordance with the present embodiment, the first through third heat treatment processes having differing control temperatures are executed as previously described. As a result, crystal growth is generated from the electrode layer 25 (titanium silicide (TiSi₂)) as a crystal nucleus or crystal seed, and whole of the semiconductor layer 24 is uniformly crystallized, including almost no crystal grain boundaries. That is to say, the method of manufacturing a nonvolatile semiconductor memory device in accordance with the embodiment can provide a nonvolatile semiconductor memory device having high reliability, which effectively suppresses occurrence of a false setting operation at a time of a reset operation while at the same time lowers power consumption.

This concludes description of embodiments in accordance with the present invention, but it should be noted that the present invention is not limited to the above-described embodiments, and that various alterations, additions, and so on, are possible within a range not departing from the scope and spirit of the invention.

For example, in the above-described embodiment, the electrode layer (titanium silicide TiSi₂) 25 may be provided between the semiconductor layer 24 and the electrode layer 23 instead of between the semiconductor layer 24 and the electrode layer 26.

For example, the electrode layer 25 may be one made from nickel silicide (NiSi₂) or palladium silicide (PdSi₂), as well as from titanium silicide (TiSi₂).

For example, the electrode layers 23, 26, 28 may be such as platinum (Pt), tungsten (W), tungsten nitride (WN), tantalum nitride (TaN), niobium (Nb)-doped titanium oxide (TiO₂), as well as titanium nitride (TiN).

For example, arsenic (As) was used as an n type impurity but phosphorus (P) may also be used. Moreover, by changing injected atoms used in an ion injection, a diode DI with a different lamination structure can be formed.

For example, in the above-described example, a method of injecting impurity atoms into a silicon film formed by un-doped CVD deposition is used to form the diode DI; however, it is also possible to form the diode using doped CVD deposition. In this case, addition of AsH₃ gas for doping with arsenic (As), addition of PH3 gas for doping with phosphorus (P), and addition of BCl₃ gas for doping with boron (B) may be used, wherein adjusting a doping amount during deposition allows a desired impurity concentration distribution to be obtained.

What is claimed is:

1. A method of manufacturing a nonvolatile semiconductor memory device comprising memory cells including a rectifier and a variable resistor connected in series,
the method including forming a layer as the rectifier element, the method of forming a layer as the rectifier element further includes:
forming a first electrode layer, a semiconductor layer and a second electrode layer; and
forming a third electrode layer between the first electrode layer and the semiconductor layer or between the second electrode layer and the semiconductor layer,
the method of forming the semiconductor layer and the third electrode layer further including:
depositing a first layer, the first layer being formed of amorphous silicon and including a p type first semiconductor region and a n type second semiconductor region;
depositing a second layer, the second layer formed of metal and on an upper layer or a lower layer of the first layer;
siliciding the second layer by heat treatment at a first temperature to form the third electrode layer formed of a metal silicide as a material lattice-matched with respect to polysilicon;
crystallizing the first layer by heat treatment at a second temperature; and
activating an impurity included in the first layer and restoring crystal imperfection included in the first layer by heat treatment at a third temperature to form the semiconductor layer.

2. The method of manufacturing a nonvolatile semiconductor memory device according to claim 1, wherein
the first layer is crystallized, by heat treatment at the second temperature, from the third electrode layer as a starting point and at least beyond a boundary between the first semiconductor region and the second semiconductor region.

3. The method of manufacturing a nonvolatile semiconductor memory device according to claim 1,
wherein
the first temperature is higher than the second temperature, and
the third temperature is higher than the first temperature.

4. The method of manufacturing a nonvolatile semiconductor memory device according to claim 3, wherein
the first layer is crystallized, by heat treatment at the second temperature, from the third electrode layer as a starting point and beyond a boundary between the first semiconductor region and the second semiconductor region.

5. The method of manufacturing a nonvolatile semiconductor memory device according to claim 1,
wherein lattice mismatching between the metal silicide and polysilicon is 2.5% or less.

6. The method of manufacturing a nonvolatile semiconductor memory device according to claim 1, wherein
the first temperature is 550° C.±20° C.,
the second temperature is 500° C.±20° C., and
the third temperature is 800° C.±20° C.

7. The method of manufacturing a nonvolatile semiconductor memory device according to claim 1, wherein
crystallizing the first layer by heat treatment at the second temperature is conducted by crystallizing the first layer using the third electrode layer as a crystal nucleus.

8. The method of manufacturing a nonvolatile semiconductor memory device according to claim 7, wherein
the second temperature is 500° C.±20° C.

9. The method of manufacturing a nonvolatile semiconductor memory device according to claim 1,
wherein
the second semiconductor region includes an n+ type semiconductor region having a first impurity concentration, and an n− type semiconductor region having a second impurity concentration lower than the first impurity concentration and in contact with the first semiconductor region.

10. The method of manufacturing a nonvolatile semiconductor memory device according to claim 9, wherein
the first layer is crystallized, by heat treatment at the second temperature, from the third electrode layer as a starting point and beyond a boundary between the first semiconductor region and the second semiconductor region.

11. The method of manufacturing a nonvolatile semiconductor memory device according to claim 9, wherein
the first temperature is higher than the second temperature, and
the third temperature is higher than the first temperature.

12. The method of manufacturing a nonvolatile semiconductor memory device according to claim 9,
wherein
lattice mismatching of the metal silicide and polysilicon is 2.5% or less.

13. The method of manufacturing a nonvolatile semiconductor memory device according to claim 9,
wherein
the first temperature is 550° C.±20° C.,
the second temperature is 500° C.±20° C., and
the third temperature is 800° C.±20° C.

14. The method of manufacturing a nonvolatile semiconductor memory device according to claim 9, wherein
crystallizing the first layer by heat treatment at the second temperature is conducted by crystallizing the first layer using the third electrode layer as a crystal nucleus.

15. The method of manufacturing a nonvolatile semiconductor memory device according to claim 14,
wherein
the second temperature is 500° C.±20° C.

16. A nonvolatile semiconductor memory device, comprising:
a plurality of first lines and a plurality of second lines formed so as to intersect with each other, and memory cells each disposed at each of intersections of the first lines and the second lines and including a rectifier and a variable resistor connected in series,
the rectifier comprising:
a semiconductor layer;
a first electrode layer provided at one side of the semiconductor layer;
a second electrode layer provided at the other side of the semiconductor layer; and
a third electrode layer provided between the first electrode layer and the semiconductor layer or between the second electrode layer and the semiconductor layer,
the semiconductor layer comprising:
a p type first semiconductor layer; and
an n type second semiconductor layer,
the third electrode layer being formed of a material lattice-matched with respect to the semiconductor layer, and the semiconductor layer has crystal growth generated from the third electrode layer as a crystal nucleus to at least beyond a boundary between the first semiconductor layer and the second semiconductor layer.

17. The nonvolatile semiconductor memory device according to claim 16, wherein
the semiconductor layer is made from polysilicon, and
the third electrode layer is made from a metal silicide.

18. The nonvolatile semiconductor memory device according to claim 16,
wherein
lattice mismatching of the metal silicide and silicon is 2.5% or less.
